(19) United States
(12) Patent Application Publication
(10) Pub. No.: US 2026/0205136 A1
(43) Pub. Date: Jul. 16, 2026

(54) METHOD TO REDUCE IMPACT OF DEVICE LEAKAGE IN CURRENT DIGITAL-TO-ANALOG CONVERTER

(71) Applicant: QUALCOMM Incorporated, San Diego, CA (US)

(72) Inventors: Karthik NAGARAJAN, Cupertino, CA (US); Sungmin OCK, San Diego, CA (US); Roi NAOR, Cork (IE)

(21) Appl. No.: 18/980,674

(22) Filed: Dec. 13, 2024

(51) Int. Cl. H03M 1/74

(52) U.S. Cl. CPC H03M 1/745

(57) ABSTRACT

A system includes a bias circuit configured to generate a bias voltage and output the bias voltage at an output of the bias circuit. The system also includes a current cell. The current cell includes a bias transistor, wherein a gate of the bias transistor is coupled to the output of the bias circuit. The current cell also includes a first switch, wherein the first switch and the bias transistor are coupled in series between an internal node and a ground. The current cell further includes a second switch coupled between the internal node and an output of the current cell, wherein a control input of the second switch is coupled to a control input of the first switch. The current cell further includes a third switch coupled between a reference voltage and the internal node.

### BACKGROUND

### Field

Aspects of the present disclosure relate generally to digital-to-analog converters (DACs), and more particularly, to current DACs.

### Background

A current digital-to-analog converter (DAC) is a DAC configured to generate an output current based on a DAC code (i.e., digital code). The output current may be input to a current-controlled circuit to control a parameter of the current-controlled circuit based on the DAC code. An example of a current-controlled circuit includes a current-controlled oscillator having a frequency that is controlled by the amount of current provided to the oscillator. In this example, the output current of the current DAC is input to the current-controlled oscillator to control the frequency of the current-controlled oscillator based on the DAC code.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a bias circuit configured to generate a bias voltage and output the bias voltage at an output of the bias circuit. The system also includes a current cell. The current cell includes a bias transistor, wherein a gate of the bias transistor is coupled to the output of the bias circuit. The current cell also includes a first switch, wherein the first switch and the bias transistor are coupled in series between an internal node and a ground. The current cell further includes a second switch coupled between the internal node and an output of the current cell, wherein a control input of the second switch is coupled to a control input of the first switch. The current cell further includes a third switch coupled between a reference voltage and the internal node.

A second aspect relates to a system. The system includes a bias circuit configured to generate a bias voltage and output the bias voltage at an output of the bias circuit. The system also includes a current digital-to-analog converter (DAC) including current cells coupled in parallel. Each of the current cells includes a respective bias transistor, wherein a gate of the respective bias transistor is coupled to the output of the bias circuit. Each of the current cells also includes a respective first switch, wherein the respective first switch and the respective bias transistor are coupled in series between a respective internal node and a ground. Each of the current cells also includes a respective second switch coupled between the respective internal node and an output of the current DAC, wherein a control input of the respective second switch is coupled to a control input of the respective first switch. Each of the current cells also includes a respective third switch coupled between a reference voltage and the respective internal node.

### BRIEF DESCRIPTION OF THE DRAWINGS

FIG. 1 shows an example of a current DAC according to certain aspects of the present

disclosure.

FIG. 2A shows an example of a current cell according to certain aspects of the present disclosure.

FIG. 2B shows an example of the current cell of FIG. 2A in which leakage current is redirected to an alternate current path according to certain aspects of the present disclosure.

FIG. 3 shows an example of an inverter for generating a complementary control signal for the current cell of FIG. 2A according to certain aspects of the present disclosure.

FIG. 4A shows an example of a current DAC including multiple instances of the current cell of FIG. 2A according to certain aspects of the present disclosure.

FIG. 4B shows an example of the current DAC of FIG. 4A further including inverters according to certain aspects of the present disclosure.

FIG. 5 shows another example of a current cell according to certain aspects of the present disclosure.

FIG. 6 shows an example of an inverter for generating a complementary control signal for the current cell of FIG. 5 according to certain aspects of the present disclosure.

FIG. 7A shows an example of a current DAC including multiple instances of the current cell of FIG. 5 according to certain aspects of the present disclosure.

FIG. 7B shows an example of the current DAC of FIG. 7A further including inverters according to certain aspects of the present disclosure.

FIG. 8 shows yet another example of a current cell according to certain aspects of the present disclosure.

FIG. 9 shows an example of a current DAC including multiple instances of the current cell of FIG. 8 according to certain aspects of the present disclosure.

FIG. 10 shows still another example of a current cell according to certain aspects of the present disclosure.

FIG. 11 shows an example of a current DAC including multiple instances of the current cell of FIG. 10 according to certain aspects of the present disclosure.

FIG. 12 shows an example of a bias circuit configured to generate a bias voltage according to certain aspects of the present disclosure.

FIG. 13 shows an example of a reference circuit according to certain aspects of the present disclosure.

FIG. 14 shows an exemplary implementation of the bias circuit according to certain aspects of the present disclosure.

FIG. 15 shows an exemplary implementation of the reference circuit according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

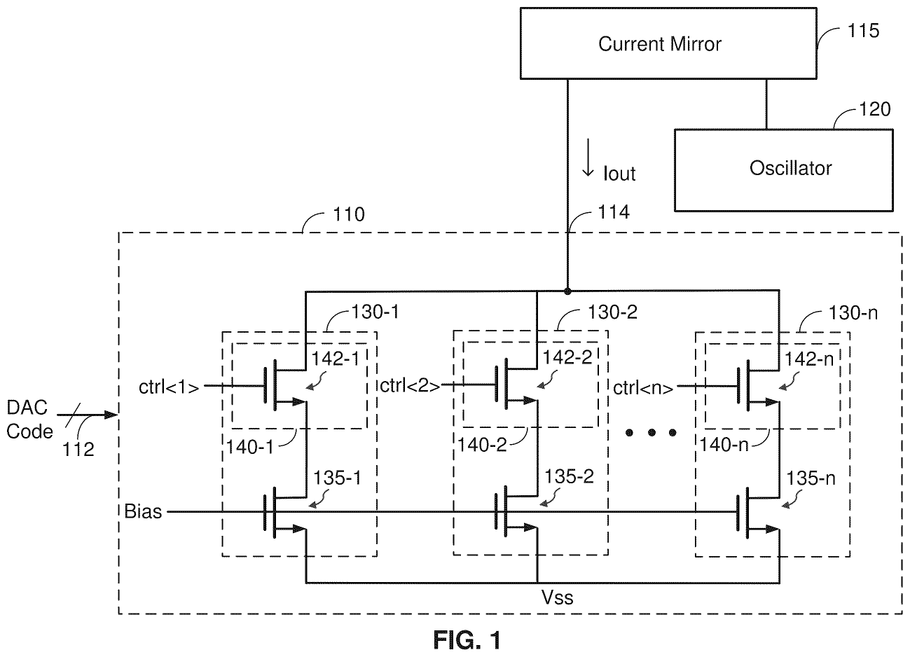

FIG. 1 shows an example of a current DAC 110 having an input 112 and an output 114. The current DAC 110 is configured to receive a DAC code (i.e., digital code) at the input 112 and provide an output current (labeled “Iout”) at the output 114 based on the DAC code. In the example shown in FIG. 1, the output current is provided to a current-controlled oscillator 120 using a current mirror 115 to control the frequency of the current-controlled oscillator 120.

In the example shown in FIG. 1, the current DAC 110 includes multiple current cells 130-1 to 130-n coupled in parallel. Each of the current cells 130-1 to 130-n includes a respective bias transistor 135-1 to 135-n and a respective switch 140-1 to 140-n. Each of the bias transistors 135-1 to 135-n is biased by a bias voltage (labeled “Bias”) to generate a respective current based on the bias voltage. In the example shown in FIG. 1, each of the bias transistors 135-1 to 135-n is implemented with a respective n-type field effect transistor (NFET) in which the bias voltage biases the gate of the respective NFET. The bias voltage may be generated by a current mirror based on a reference current, an amplifier, or the like.

Each of the switches 140-1 to 140-n is coupled in series with the respective bias transistor 135-1 to 135-n . In this example, each of the switches 140-1 to 140-n controls whether the current of the respective bias transistor 135-1 to 135-n contributes to the output current (labeled “Iout”) of the current DAC 110. More particularly, when a switch is turned on, the current of the respective bias transistor contributes to the output current of the current DAC 110, and, when a switch is turned off, the respective bias transistor ideally does not contribute any current to the output current of the current DAC 110. Thus, the output current of the current DAC 110 can be controlled by controlling the number of the switches 140-1 to 140-n that are turned on.

In certain aspects, the DAC code may include multiple control signals ctrl<1> to ctrl<n> (e.g., control bits), in which each of the control signals ctrl<1> to ctrl<n> controls the on/off state of a respective one of the switches 140-1 to 140-n . For example, each of the switches 140-1 to 140-n may be configured to turn on when the respective control signal has a first logic state and turn off when the respective control signal has a second logic state. The first logic state may be one (e.g., a supply voltage) and the second logic state may be zero (e.g., ground potential), or vice versa. In the example shown in FIG. 1, each of the switches 140-1 to 140-n is implemented with a respective transistor 142-1 to 142-n (e.g., respective NFET) in which the respective control signal is input to the gate of the respective transistor 142-1 to 142-n.

In this example, the DAC code controls the output current of the current DAC 110 by controlling the number of the switches 140-1 to 140-n that are turned on. For example, the DAC code may increase the output current by increasing the number of the switches 140-1 to 140-n that are turned on and decrease the output current by decreasing the number of the switches 140-1 to 140-n that are turned on.

Ideally, a switch that is turned off has zero current so that the output current of the current DAC 110 is determined by the number of the switches 140-1 to 140-n that are turned on based on the DAC code. However, in advanced process nodes, the transistors implementing the switches 140-1 to 140-n have become leakier. As a result, leakage currents from switches that are turned off contribute to the output current of the current DAC 110. The contribution of the leakage currents negatively impacts the accuracy of the output current. For low DAC codes, the leakage currents contribute a larger portion of the output current, making the accuracy of the output current even worse for low DAC codes. In addition, the leakage currents are sensitive to temperature, which causes the frequency of the oscillator 120 to change with temperature for a given DAC code.

Accordingly, there is a need to reduce the impact of leakage currents on the output current of the current DAC 110.

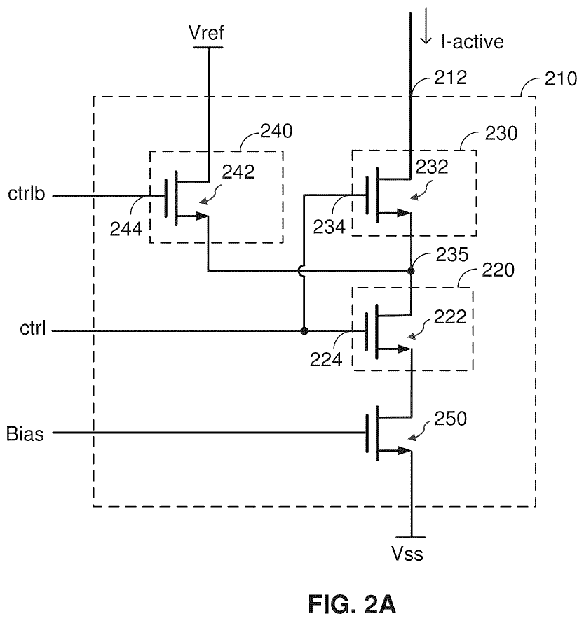

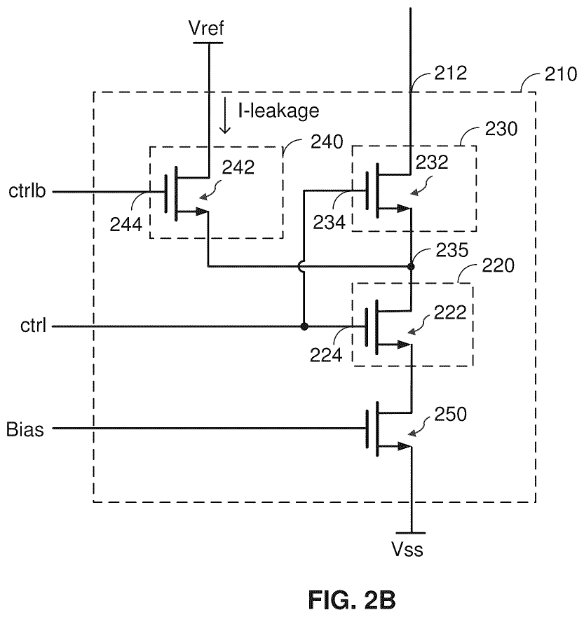

FIG. 2A shows an example of a current cell 210 that reduces the impact of leakage current on the output current of a current DAC according to certain aspects. Multiple instances of the current cell 210 may be coupled in parallel to form the current DAC, as discussed further below. The current cell 210 may also be referred to as a DAC cell or another term.

The current cell 210 includes a bias transistor 250 that is biased by a bias voltage (labeled “Bias”) to generate an active current (labeled “I-active”) based on the bias voltage. In the example shown in FIG. 2A, the gate of the bias transistor 250 (e.g., an NFET) is biased by the bias voltage. The bias voltage may be generated by a current mirror based on a reference current, an amplifier, or the like. The bias transistor 250 may also be referred to as a current source or another term.

The current cell 210 also includes a first switch 220, a second switch 230, and a third switch 240. The first switch 220 and the bias transistor 250 are coupled in series between an internal node 235 and a ground. In this example, the first switch 220 is coupled between the internal node 235 and the bias transistor 250, and the bias transistor 250 is coupled between the first switch 220 and the ground. The first switch 220 has a control input 224 configured to receive a control signal ctrl for controlling the on/off state of the first switch 220. In the example shown in FIG. 2A, the first switch 220 includes a transistor 222 (e.g., an NFET) in which the control input 224 of the first switch 220 corresponds to the gate of the transistor 222.

The second switch 230 is coupled between the internal node 235 and the output 212 of the current cell 210. The second switch 230 has a control input 234 configured to receive the control signal ctrl for controlling the on/off state of the second switch 230. In this example, the control input 234 of the second switch 230 and the control input 224 of the switch 220 are coupled together since the control inputs 234 and 224 receive the same control signal ctrl. Thus, in this example, the on/off states of the first switch 220 and the second switch 230 are controlled by the same control signal ctrl. In the example shown in FIG. 2A, the second switch 230 includes a transistor 232 (e.g., an NFET) in which the control input 234 of the second switch 230 corresponds to the gate of the transistor 232.

The third switch 240 is coupled between the internal node 235 and a reference voltage (labeled “Vref”). The reference voltage may be a supply voltage or an internal voltage of a reference circuit, as discussed further below. In the example shown in FIG. 2A, the third switch 240 has a control input 244 configured to receive a control signal ctrlb that is the complement (i.e., inverse) of the control signal ctrl. As discussed further below, the complementary control signals ctrl and ctrlb are used to cause the third switch 240 to turn off when the first switch 220 and the second switch 230 are turned on and cause the third switch 240 to turn on when the first switch 220 and the second switch 230 are turned off. In the example shown in FIG. 2A, the third switch 240 includes a transistor 242 (e.g., an NFET) in which the control input 244 of the third switch 240 corresponds to the gate of the transistor 242.

During operation, when the first switch 220 and the second switch 230 are turned on by the control signal ctrl, the third switch 240 is turned off by the control signal ctrlb (which is the complement of the control signal ctrl). As a result, the active current (labeled “I-active) from the bias transistor 250 flows through the first switch 220 and the second switch 230 and contributes to the output current of the current DAC. In this case, the current cell 210 may be considered active.

When the first switch 220 and the second switch 230 are turned off by the control signal ctrl, the third switch 240 is turned on by the control signal ctrlb. As a result, the third switch 240 provides an alternate current path for the leakage current. In this regard, FIG. 2B shows an example of the alternate current path, which allows the leakage current (labeled “I-leakage”) to flow between the reference voltage and the internal node 235 through the third switch 240 (which is turned on). As a result, the leakage current flows through the alternate current path instead of the output 212 of the current cell 210 (i.e., the leakage current is redirected to the alternate current path). Because the leakage current flows through the alternate current path, the leakage current has little to no impact on the output current of the current DAC. In this case, the current cell 210 may be considered inactive.

In this example, the bias voltage (labeled “Bias”) continues to bias the bias transistor 250 when the current cell 210 is inactive. In this case, the first switch 220 (which is turned off) prevents the bias transistor 250 from generating the active current (labeled “I-active”) and the third switch 240 (which is turned on) redirects the leakage current (labeled “I-leakage”) to the alternate current path. Because the bias voltage (labeled “Bias”) continues to bias the bias transistor 250 when the current cell 210 is inactive, the bias voltage is not disturbed when the current cell 210 switches between being inactive and active. For cases where the current cell 210 shares the bias voltage with other current cells that remain active, this prevents disturbances in the bias voltage from impacting the currents of the other current cells.

The second switch 230 helps block the leakage current from the output 212 of the current cell 210 when the current cell 210 is inactive. This is because the second switch 230 has a much lower conductivity than the alternate current path when the second switch 230 is turned off and the third switch 240 is turned on. As a result, the leakage current flows through the alternate current path away from the output 212.

For the example where the transistor 232 of the second switch 230 is implemented with an NFET, the second switch 230 may be turned off when the current cell 210 is inactive by setting the control signal ctrl at the gate of the transistor 232 to ground potential. In this case, the source of the transistor 232 is coupled to the reference voltage (labeled “Vref”) through the third switch 240 (which is turned on). Since the reference voltage is greater than ground potential, this causes the gate-to-source voltage of the transistor 232 to be negative. The negative gate-to-source voltage further reduces the conductivity of the second switch 230, which helps redirect the leakage current to the alternate current path and away from the output 212.

In the example shown in FIGS. 2A and 2B, each of the transistors 222, 232, and 242 of the switches 220, 230, and 240 is implemented with a respective NFET. Thus, in this example, the first switch 220 and the second switch 230 turn on when the control signal ctrl is high (e.g., supply voltage) and turn off when the control signal ctrl is low (e.g., ground potential). Also, the third switch 240 turns off when the control signal ctrlb is low (e.g., ground potential) and turns on when the control signal ctrlb is high (e.g., the supply voltage). Because the control signals ctrl and ctrlb are complementary, the third switch 240 is turned off when the first switch 220 and the second switch 230 are turned on, and the third switch 240 is turned on when the first switch 220 and the second switch 230 are turned off.

For the example where each of the transistors 222, 232, and 242 of the switches 220, 230, and 240 is implemented with a respective NFET, the drain of the transistor 222 is coupled to the internal node 235 and the source of the transistor 222 is coupled to the bias transistor 250. The drain of the transistor 232 is coupled to the output 212 of the current cell 210 and the source of the transistor 232 is coupled to the internal node 235. Also, the drain of the transistor 242 is coupled to the reference voltage and the source of the transistor 242 is coupled to the internal node 235. For the example where the bias transistor 250 is implemented with an NFET, the drain of the bias transistor 250 is coupled to the source of the transistor 222 and the source of the bias transistor 250 is coupled to ground.

As discussed above, the reference voltage (labeled “Vref”) may be a supply voltage or an internal voltage of a reference circuit. For the example where the reference voltage is the supply voltage, the third switch 240 is coupled between the supply rail (which provides the supply voltage) and the internal node 235 (e.g., the drain of the transistor 242 is coupled to the supply rail). For the example where the reference voltage is the internal voltage of the reference circuit, the third switch 240 is coupled between the reference circuit and the internal node 235 (e.g., the drain of the transistor 242 is coupled to the reference circuit).

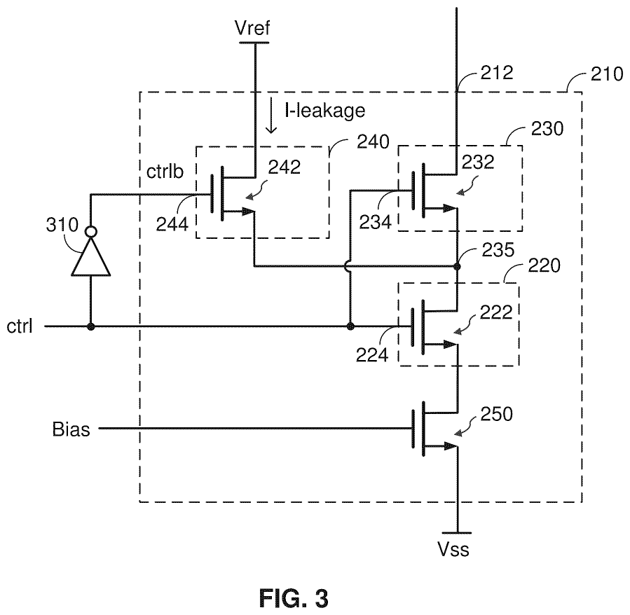

In certain aspects, the control signal ctrlb for the third switch 240 may be generated by inverting the control signal ctrl. In this regard, FIG. 3 shows an example of an inverter 310 coupled between the control input 224 of the first switch 220 and the control input 244 of the third switch 240. In this example, the input of the inverter 310 is coupled to the control input 224 of the first switch 220 and the output of the inverter 310 is coupled to the control input 244 of the third switch 240. As a result, the inverter 310 inverts the control signal ctrl to generate the control signal ctrlb for the third switch 240.

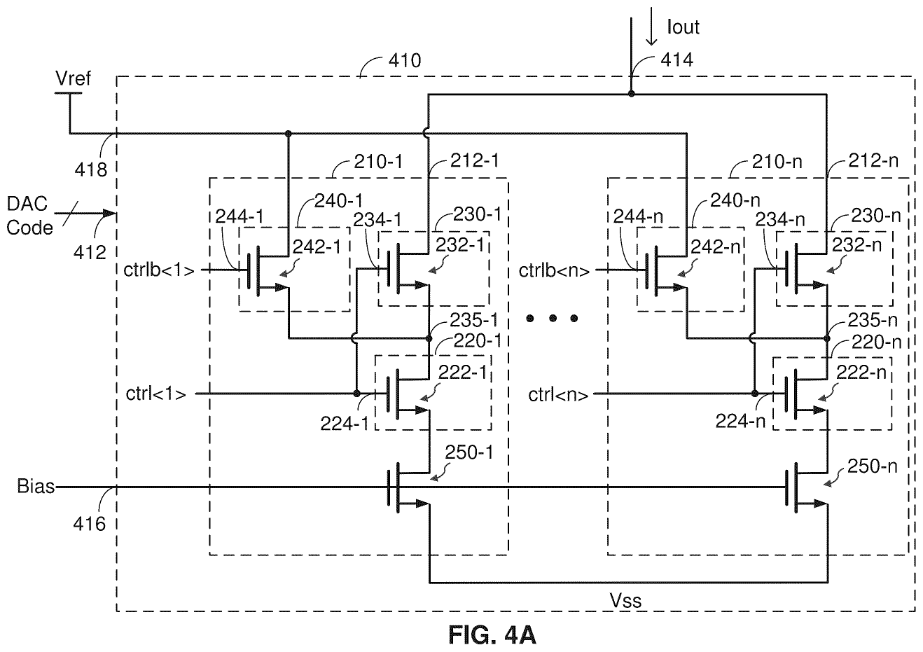

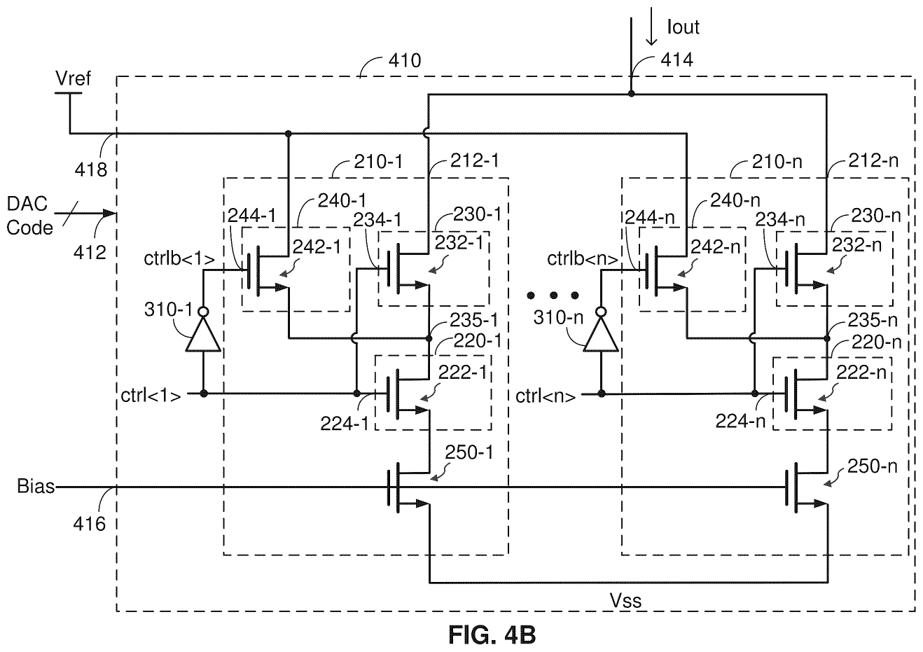

As discussed above, multiple instances (i.e., copies) of the current cell 210 may be coupled in parallel to form a current DAC. In this regard, FIG. 4A shows an example of a current DAC 410 including multiple current cells 210-1 to 210-n coupled in parallel where each of the current cells 210-1 to 210-n is a separate instance of the current cell 210. Since each of the current cells 210-1 to 210-n is an instance of the current cell 210, the description of the current cell 210 given above is applicable to each of the current cells 210-1 to 210-n.

In the example in FIG. 4A, the current DAC 410 has a first input 412 configured to receive the DAC code (i.e., digital code), a second input 416 configured to receive the bias voltage (labeled “Bias”), and a third input 418 coupled to the reference voltage (labeled “Vref”). In this example, the second input 416 is coupled to the respective bias transistor 250-1 to 250-n of each of the current cells 210-1 to 210-n to bias the respective bias transistor 250-1 to 250-n with the bias voltage (labeled “Bias”). Thus, in this example, the bias voltage is shared among the bias transistors 250-1 to 250-n of the current cells 210-1 to 210-n. Also, in this example, the respective third switch 240-1 to 240-n of each of the current cells 210-1 to 210-n is coupled between the respective internal node 235-1 to 235-n and the third input 418 (which is coupled to the reference voltage).

The current DAC 410 also has an output 414 configured to provide the output current (labeled “Iout”) of the current DAC 410 based on the DAC code. In the example shown in FIG. 4A, the current cells 210-1 to 210-n are coupled in parallel between the output 414 and the ground. In this example, the output 212-1 to 212-n of each of the current cells 210-1 to 210-n is coupled to the output 414 of the current DAC 410 so that the currents of the active ones of the current cells 210-1 to 210-n contribute to the output current of the current DAC 410.

In this example, the DAC code (i.e., digital code) includes multiple control signals ctrl<1> to ctrl<n>, in which each of the control signals ctrl<1> to ctrl<n> is input to a respective one of the current cells 210-1 to 210-n to control whether the respective one of the current cells 210-1 to 210-n is active or inactive. In certain aspects, the DAC code may be a thermometer code including the control signals ctrl<1> to ctrl<n> where each of the control signals controls a respective one of the current cells 210-1 to 210-n. In these aspects, the DAC code may be generated from a binary code using a binary-to-thermometer decoder (not shown) in which the binary code includes a binary number indicating an output current setting for the current DAC 410. The binary-to-thermometer decoder may translate the binary number into individual control signals (i.e., the control signals ctrl<1> to ctrl<n>) for the current cells 210-1 to 210-n.

In each of the current cells 210-1 to 210-n, the respective one of the control signals ctrl<1> to ctrl<n> is input to the control input 224-1 to 224-n of the respective first switch 220-1 to 220-n and the control input 234-1 to 234-n of the respective second switch 230-1 to 230-n. Also, in each of the current cells 210-1 to 210-n, the complement (i.e., inverse) of the respective one of the control signals ctrl<1> to ctrl<n> (i.e., ctrlb<1> to ctrlb<n>) is input to the control input 244-1 to 244-n of the respective third switch 240-1 to 240-n. The inverse control signal for each of the current cells 210-1 to 210-n may be generated by inverting the respective control signal using a respective inverter.

In this example, each of the current cells 210-1 to 210-n is active when the respective one of the control signals ctrl<1> to ctrl<n> is high (e.g., the supply voltage), and each of the current cells 210-1 to 210-n is inactive when the respective one of the control signals ctrl<1> to ctrl<n> is low (e.g., ground potential). In this example, the output current (labeled “Iout”) of the current DAC 410 is equal to the sum of the currents of the active ones of the current cells 210-1 to 210-n. This allows the control signals ctrl<1> to ctrl<n> of the DAC code to control the output current of the current DAC 410 by controlling the number of the current cells 210-1 to 210-n that are active. For example, the DAC code may increase the output current by increasing the number of the current cells 210-1 to 210-n that are active and decrease the output current by decreasing the number of the current cells 210-1 to 210-n that are active. In this example, the leakage currents of the inactive ones of the current cells 210-1 to 210-n are redirected to the respective alternate current paths to prevent the leakage currents from contributing to the output current of the current DAC 410.

In the example shown in FIG. 4A, the bias voltage (labeled “Bias”) is shared by the bias transistors 250-1 to 250-n of the current cells 210-1 to 210-n. The bias voltage biases the bias transistors 250-1 to 250-n of both active and inactive current cells 210-1 to 210-n. This prevents disturbances in the bias voltage when the DAC code switches one or more of the current cells 210-1 to 210-n between inactive and active.

FIG. 4B shows an example in which the current DAC 410 also includes inverters 310-1 to 310-n. Each of the inverters 310-1 to 310-n corresponds to a respective one of the current cells 210-1 to 210-n and is used to generate the respective complementary control signal. For each of the current cells 210-1 to 210-n, the respective inverter 310-1 to 310-n is coupled between the control input 244-1 to 244-n of the respective third switch 240-1 to 240-n and the control input 224-1 to 224-n of the respective first switch 220-1 to 220-n.

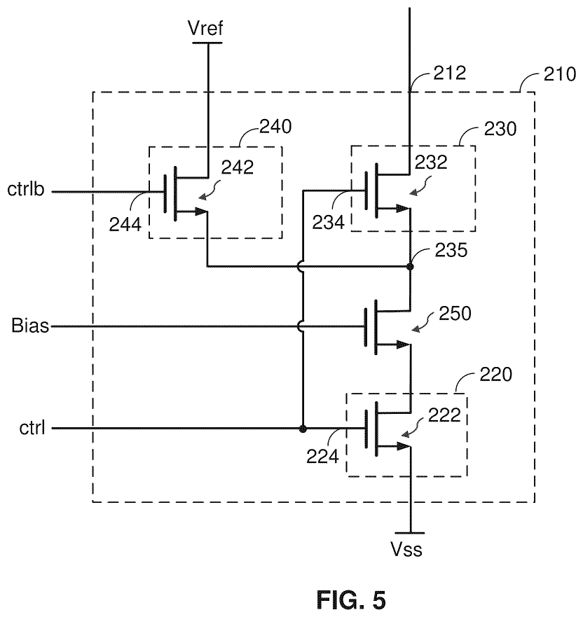

The current cell 210 is not limited to the exemplary implementation shown in FIGS. 2A and 2B. In this regard, FIG. 5 shows another exemplary implementation of the current cell 210 in which the first switch 220 is relocated to act as a footer switch for the bias transistor 250. In this example, the first switch 220 is coupled between the bias transistor 250 and the ground, and the bias transistor 250 is coupled between the internal node 235 and the first switch 220. In both of the exemplary implementations shown in FIGS. 2A, 2B, and FIG. 5, the first switch 220 and the bias transistor 250 are coupled in series between the internal node 235 and the ground.

For the example where the transistor 222 of the first switch is implemented with an NFET, the drain of the transistor 222 is coupled to the bias transistor 250 and the source of the transistor 222 is coupled to ground. For the example where the bias transistor 250 is implemented with an NFET, the drain of the bias transistor 250 is coupled to the internal node 235 and the source of the bias transistor 250 is coupled to the drain of the transistor 222.

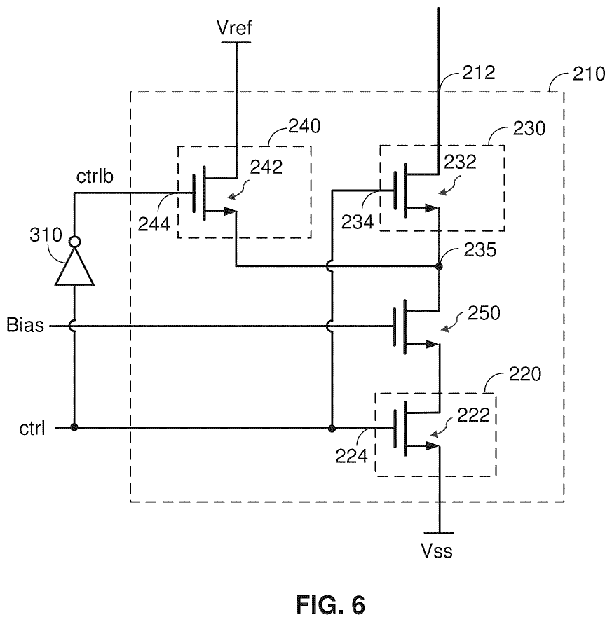

In certain aspects, the control signal ctrlb for the third switch 240 may be generated by inverting the control signal ctrl. In this regard, FIG. 6 shows an example of the inverter 310 coupled between the control input 224 of the first switch 220 and the control input 244 of the third switch 240. In this example, the inverter 310 inverts the control signal ctrl to generate the control signal ctrlb for the third switch 240.

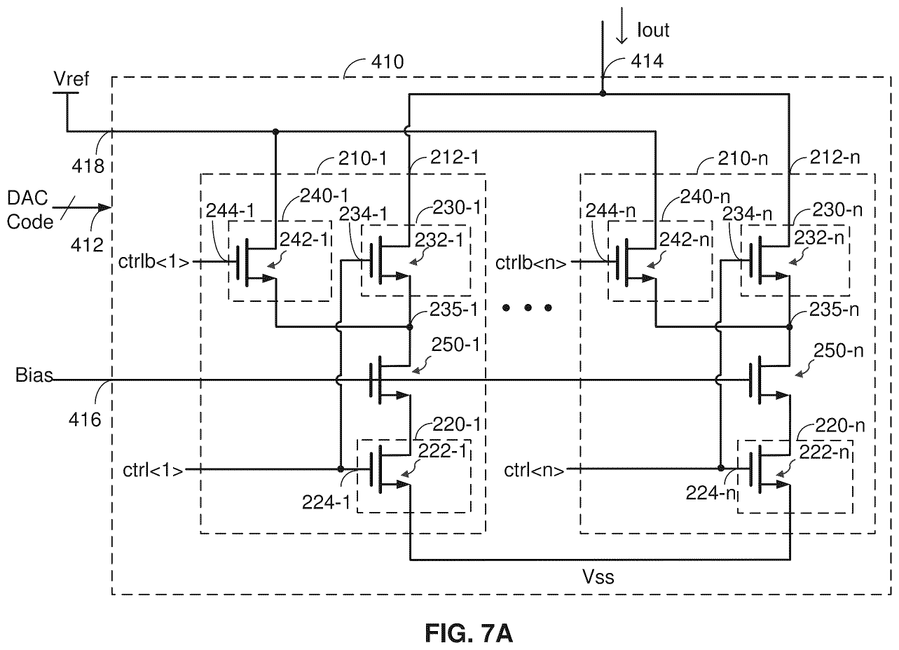

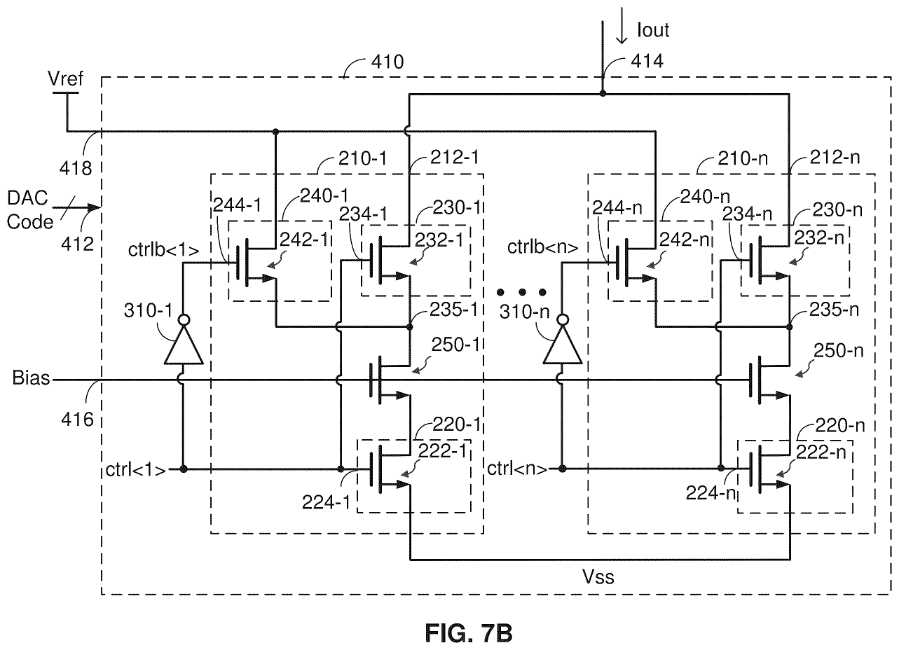

FIG. 7A shows an example of the current DAC 410 in which each of the current cells 210-1 to 210-n is a separate instance of the current cell 210 shown in FIG. 5. In this example, the respective first switch 220-1 to 220-n of each of the current cells 210-1 to 210-n is coupled between the respective bias transistor 250-1 to 250-n and the ground. In other words, the respective first switch 220-1 to 220-n of each of the current cells 210-1 to 210-n is used as a footer switch for the respective bias transistor 250-1 to 250-n.

FIG. 7B shows an example in which the current DAC 410 also includes inverters 310-1 to 310-n. Each of the inverters 310-1 to 310-n corresponds to a respective one of the current cells 210-1 to 210-n and is used to generate the respective complementary control signal. For each of the current cells 210-1 to 210-n, the respective inverter 310-1 to 310-n is coupled between the control input 244-1 to 244-n of the respective third switch 240-1 to 240-n and the control input 224-1 to 224-n of the respective first switch 220-1 to 220-n.

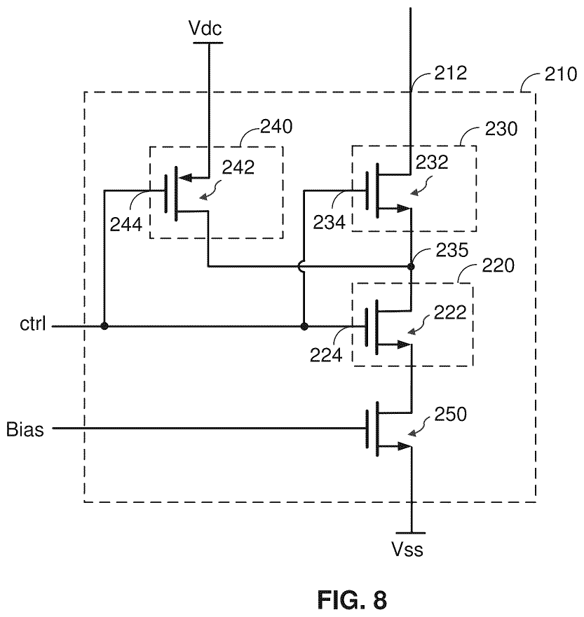

FIG. 8 shows another exemplary implementation of the current cell 210 in which the transistor 242 of the third switch 240 is implemented with a p-type field effect transistor (PFET) instead of an NFET. In this example, the control input 244 of the third switch 240 receives the control signal ctrl instead of the control signal ctrlb. Since the third switch 240 is controlled by the control signal ctrl, the control input 244 of the third switch 240 may be coupled to the control input 224 of the first switch 220 and the control input 234 of the second switch 230, as shown in FIG. 8.

In this example, the source of the transistor 242 is coupled to the reference voltage and the drain of the transistor 242 is coupled to the internal node 235. For the example where the reference voltage is the supply voltage, the source of the transistor 242 is coupled to the supply rail providing the supply voltage. For the example where the reference voltage is an internal voltage of a reference circuit, the source of the transistor 242 is coupled to the reference circuit.

In this example, the PFET implementing the transistor 242 causes the third switch 240 to turn off when the control signal ctrl is high (e.g., the supply voltage) and turn on when the control signal ctrl is low (e.g., ground potential). In contrast, the first switch 220 and the second switch 230 turn on when the control signal ctrl is high (e.g., the supply voltage) and turn off when the control signal ctrl is low (e.g., ground potential). As a result, the third switch 240 is turned on to provide the alternate current path when the first switch 220 and the second switch 230 are turned off. The third switch 240 is turned off when the first switch 220 and the second switch 230 are turned on to provide the active current of the bias transistor 250 at the output 212.

In the exemplary implementations shown in FIGS. 2A, 2B, FIG. 5, and FIG. 8, the second switch 230 and the third switch 240 are complementary switches (i.e., the third switch 240 is turned off when the second switch 230 is turned on and the third switch 240 is turned on when the second switch 230 is turned off). In the exemplary implementations shown in FIGS. 2A, 2B, and FIG. 5 where the second switch 230 and the third switch 240 are implemented with NFETs, the second switch 230 and the third switch 240 are made complementary by using complementary control signals ctrl and ctrlb to control the second switch 230 and the third switch 240. In the exemplary implementation shown in FIG. 8, the second switch 230 and the third switch 240 are made complementary by using an NFET for the second switch 230 and using a PFET for the third switch 240 with the same control signal controlling both switches.

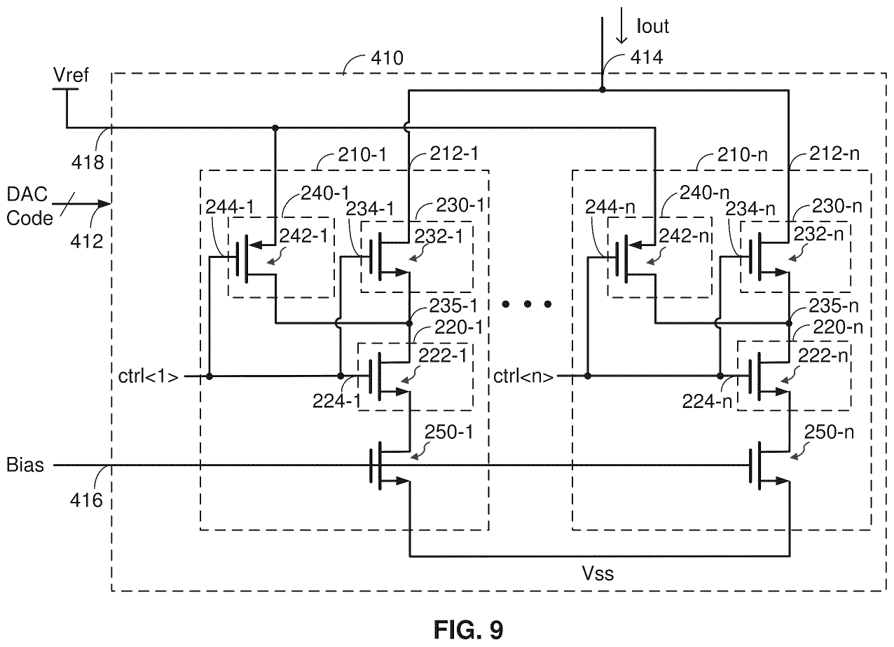

FIG. 9 shows an example of the current DAC 410 in which each of the current cells 210-1 to 210-n is a separate instance of the current cell 210 shown in FIG. 8. In this example, the respective third switch 240-1 to 240-n of each of the current cells 210-1 to 210-n is implemented with a respective PFET and is controlled by the respective one of the control signals ctrl<1> to ctrl<n>. In this example, the complementary control signals ctrlb<1> to ctrlb<n> may be omitted.

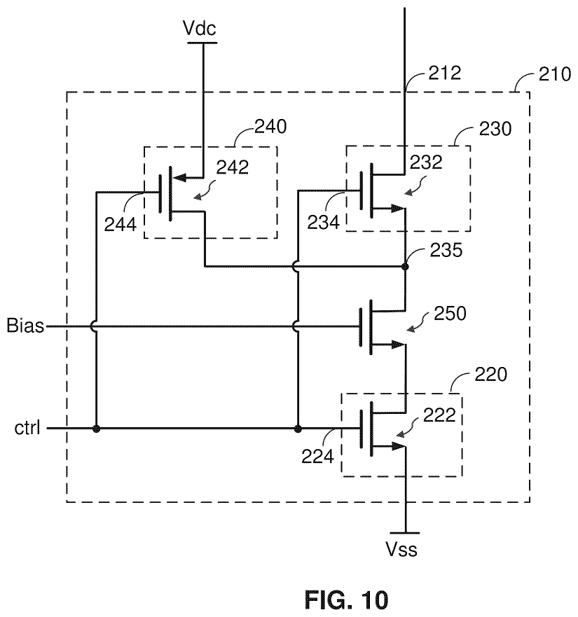

FIG. 10 shows another exemplary implementation of the current cell 210 in which the transistor 242 of the third switch 240 is implemented with the PFET and the first switch 220 is used as a footer switch for the bias transistor 250. In this example, the control input 244 of the third switch 240 receives the control signal ctrl and may be coupled to the control input 224 of the first switch 220 and the control input 234 of the second switch 230, as shown in FIG. 9. Also, in this example, the first switch 220 is coupled between the bias transistor 250 and the ground, and the bias transistor 250 is coupled between the internal node 235 and the first switch 220.

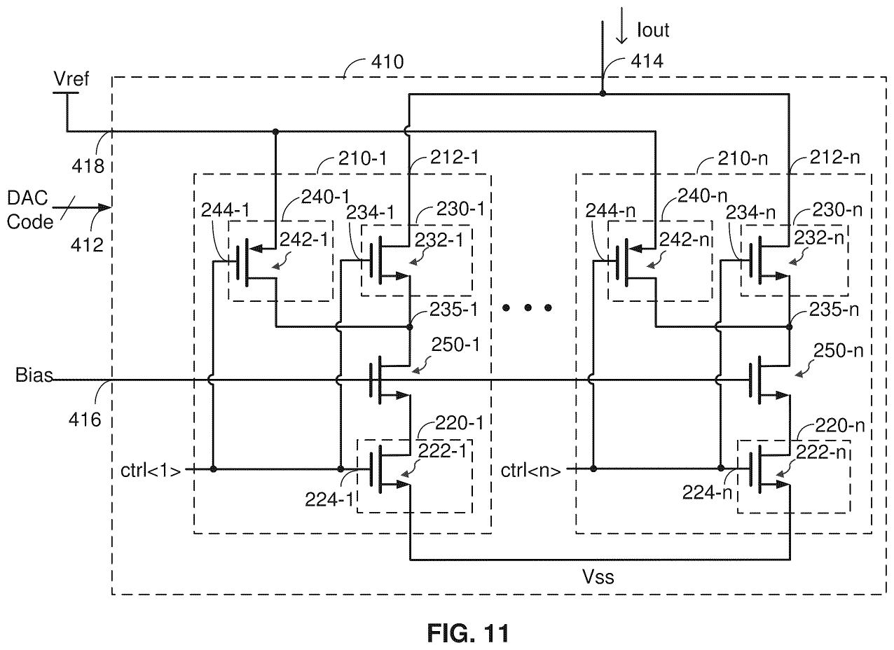

FIG. 11 shows an example of the current DAC 410 in which each of the current cells 210-1 to 210-n is a separate instance of the current cell 210 shown in FIG. 10. In this example, the respective third switch 240-1 to 240-n of each of the current cells 210-1 to 210-n is implemented with a respective PFET and is controlled by the respective one of the control signals ctrl<1> to ctrl<n>. Also, in this example, the respective first switch 220-1 to 220-n of each of the current cells 210-1 to 210-n is coupled between the respective bias transistor 250-1 to 250-n and the ground.

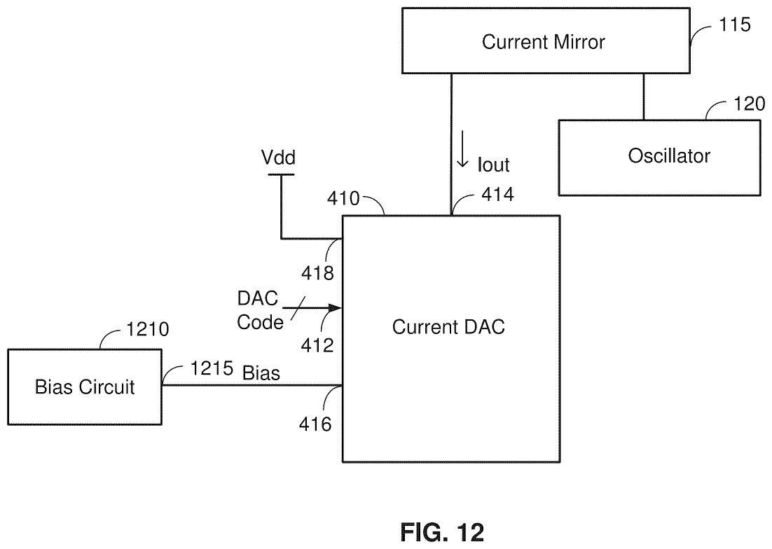

FIG. 12 shows an example of a bias circuit 1210 configured to generate the bias voltage (labeled “Bias”) according to certain aspects. For ease of illustration, the current DAC 410 is shown as a block in FIG. 12. The current DAC 410 may be implemented using any one of the exemplary implementations shown in FIGS. 4A, 4B, 7A, 7B, 9, and 11.

In this example, the bias circuit 1210 has an output 1215 coupled to the second input 416 of the current DAC 410, which is coupled to the gates of the bias transistors 250-1 to 250-n. The bias circuit 1210 is configured to output the bias voltage at the output 1215. The bias circuit 1210 may include a current mirror, a current source, an amplifier, and/or any combination thereof.

FIG. 12 also shows an example in which the reference voltage is the supply voltage (labeled “Vdd”). In this example, the third input 418 of the current DAC 410 is coupled to the supply rail providing the supply voltage. Thus, in this example, the respective third switch 240-1 to 240-n of each of the current cells 210-1 to 210-n is coupled between the supply rail and the respective internal node 235-1 to 235-n.

In the example shown in FIG. 12, the output current of the current DAC 410 is provided to the current-controlled oscillator 120 using the current mirror 115 to control the frequency of the current-controlled oscillator 120. However, it is to be appreciated that the output current of the current DAC 410 may also be provided to another current-controlled circuit to control a parameter of the other current-controlled circuit. For example, the output current of the current DAC 410 may be provided to a charge pump to control the charging and discharging currents of the charge pump.

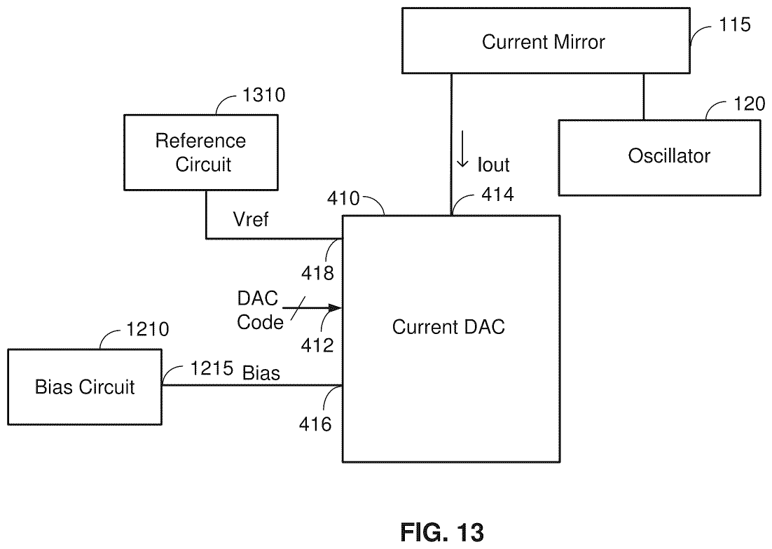

FIG. 13 shows an example of a reference circuit 1310 coupled to the third input 418 of the current DAC 410. In this example, the reference circuit 1310 is configured to generate the reference voltage (labeled “Vref”). The reference circuit 1310 may include a voltage divider, a diode-connected transistor, and/or any combination thereof.

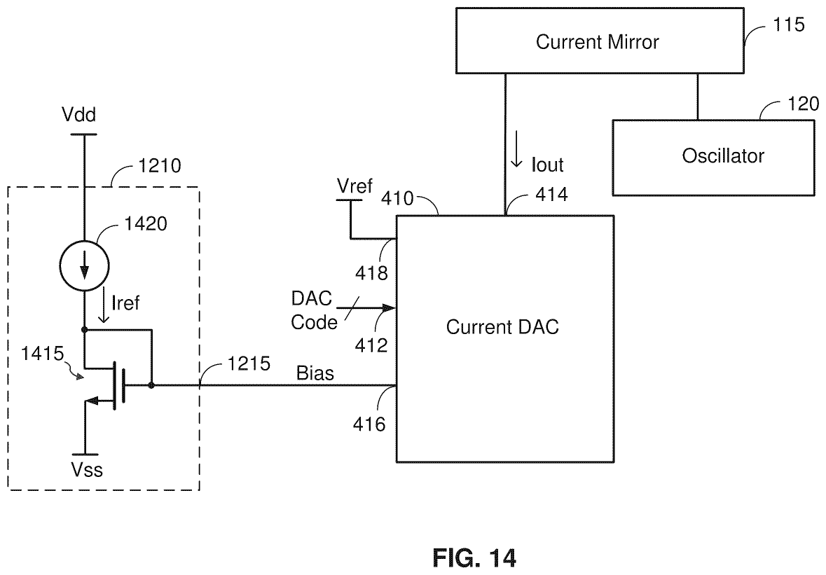

FIG. 14 shows an exemplary implementation of the bias circuit 1210. In this example, the bias circuit 1210 includes a current source 1420 and a current transistor 1415 (e.g., an NFET). The current source 1420 is configured to generate a reference current (labeled “Iref”) and is coupled between a supply rail and the drain of the current transistor 1415. The supply rail provides the supply voltage (labeled “Vdd”). The drain and the gate of the current transistor 1415 are coupled together and the source of the current transistor 1415 is coupled to the ground. The gate of the current transistor 1415 is coupled to the second input 416 of the current DAC 410, which is coupled to the bias transistors 250-1 to 250-n (not shown in FIG. 14) in the current DAC 410.

In this example, the bias circuit 1210 generates the bias voltage at the gate of the current transistor 1415 based on the reference current from the current source 1420. In this example, the bias circuit 1210 biases the bias transistors 250-1 to 250-n such that the active current of each of the bias transistors 250-1 to 250-n is approximately equal to or proportional to the reference current.

In this example, the reference voltage (labeled “Vref”) may be the supply voltage shown in FIG. 12 or the voltage output from the reference circuit 1310 shown in FIG. 13. For the example where the reference voltage is the supply voltage, the third input 418 of the current DAC 410 is coupled to the supply rail. For the example where the reference voltage is the voltage output from the reference circuit 1310, the third input 418 of the current DAC 410 is coupled to the reference circuit 1310.

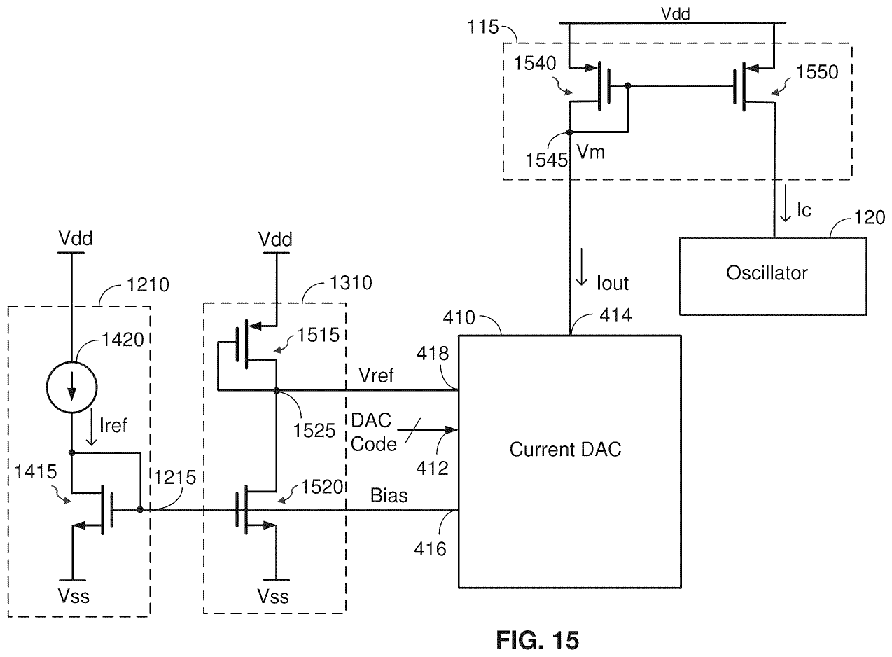

FIG. 15 shows an exemplary implementation of the reference circuit 1310 according to certain aspects. In this example, the reference circuit 1310 includes a first transistor 1515 (e.g., a PFET) and a second transistor 1520 (e.g., an NFET). In the example shown in FIG. 15, the first transistor 1515 is a diode-connected transistor in which the source of the first transistor 1515 is coupled to the supply rail and the drain and the gate of the first transistor 1515 are coupled together. The drain of the second transistor 1520 is coupled to the drain of the first transistor 1515, the gate of the second transistor 1520 is biased by the bias voltage (labeled “Bias”) from the bias circuit 1210, and the source of the second transistor 1520 is coupled to the ground.

In this example, the second transistor 1520 generates a current that is equal to or proportional to the reference current in the bias circuit 1210. The current from the second transistor 1520 flows through the first transistor 1515. The reference voltage (labeled “Vref”) is generated at a node 1525 between the first transistor 1515 and the second transistor 1520, as shown in FIG. 15. In this example, the reference voltage is approximately equal to the supply voltage minus the source-to-gate voltage of the first transistor 1515. The node 1525 is coupled to the third input 418 of the current DAC 410. As a result, the respective third switch 240-1 to 240-n of each of the current cells 210-1 to 210-n is coupled between the node 1525 and the respective internal node 235-1 to 235-n.

In the example shown in FIG. 15, the current mirror 115 includes a third transistor 1540 (e.g., a first PFET) and a fourth transistor 1550 (e.g., a second PFET). In this example, the source of the third transistor 1540 is coupled to the supply rail, the drain and the gate of the third transistor 1540 are coupled together, and the drain of the third transistor 1540 is coupled to the output 414 of the current DAC 410. The source of the fourth transistor 1550 is coupled to the supply rail, the gate of the fourth transistor 1550 is coupled to the gate of the third transistor 1540, and the drain of the fourth transistor 1550 is coupled to the current-controlled oscillator 120.

During operation, the output current (labeled “Iout”) of the current DAC 410 flows through the third transistor 1540 of the current mirror 115. Since the gate of the fourth transistor 1550 is coupled to the gate of the third transistor 1540, the output current of the current DAC 410 flowing through the third transistor 1540 is mirrored at the fourth transistor 1550 to provide a control current (labeled “Ic”) to the oscillator 120. The control current is approximately equal to or proportional to the output current of the current DAC 410 (e.g., depending on the ratio between the channel width of the fourth transistor 1550 and the channel width of the third transistor 1540). Since the control current is equal to or proportional to the output current of the current DAC 410, the output current of the current DAC 410 controls the frequency of the current-controlled oscillator 120.

FIG. 15 shows the voltage (labeled “Vm”) at the node 1545 between the drain of the third transistor 1540 and the output 414 of the current DAC 410. In this example, the voltage at the internal node 235-1 to 235-n of each of the current cells 210-1 to 210-n that is active is approximately equal to the voltage (labeled “Vm”) at the node 1545. The voltage at the internal node 235-1 to 235-n of each of the current cells 210-1 to 210-n that is inactive is approximately equal to the reference voltage (labeled “Vref”) at the node 1525.

Since both the first transistor 1515 and the third transistor 1540 are in a diode-connected configuration in this example, the reference voltage (labeled “Vref”) at the node 1525 is similar to the voltage (labeled “Vm”) at the node 1545. This reduces voltage changes at the internal nodes 235-1 to 235-n of the current cells 210-1 to 210-n due to switching one or more of the current cells 210-1 to 210-n between active and inactive, and therefore helps stabilize the voltages at the internal nodes 235-1 to 235-n of the current cells 210-1 to 210-n.

Implementation examples are described in the following numbered clauses:
1. A system, comprising:
a bias circuit configured to generate a bias voltage and output the bias voltage at an output of the bias circuit; and
a current cell, comprising:
   a bias transistor, wherein a gate of the bias transistor is coupled to the output of the bias circuit;
   a first switch, wherein the first switch and the bias transistor are coupled in series between an internal node and a ground;
   a second switch coupled between the internal node and an output of the current cell, wherein a control input of the second switch is coupled to a control input of the first switch; and
      a third switch coupled between a reference voltage and the internal node.
2. The system of clause 1, further comprising an inverter coupled between a control input of the third switch and the control input of the first switch.
3. The system of clause 2, wherein:
the first switch comprises a first n-type field effect transistor (NFET), wherein the control input of the first switch corresponds to a gate of the first NFET;
the second switch comprises a second NFET, wherein the control input of the second switch corresponds to a gate of the second NFET; and
the third switch comprises a third NFET, wherein the control input of the third switch corresponds to a gate of the third NFET.
4. The system of clause 3, wherein the bias transistor comprises a fourth NFET.
5. The system of any one of clauses 1 to 4, wherein:
the control input of the first switch and the control input of the second switch are configured to receive a first control signal; and
a control input of the third switch is configured to receive a second control signal, wherein the first control signal and the second control signal are complementary.
6. The system of clause 1, wherein a control input of the third switch is coupled to the control input of the first switch.
7. The system of clause 6, wherein:
the first switch comprises a first n-type field effect transistor (NFET), wherein the control input of the first switch corresponds to a gate of the first NFET;
the second switch comprises a second NFET, wherein the control input of the second switch corresponds to a gate of the second NFET; and
the third switch comprises a p-type field effect transistor (PFET), wherein the control input of the third switch corresponds to a gate of the PFET.
8. The system of clause 7, wherein the bias transistor comprises a third NFET.
9. The system of any one of clauses 1 to 8, wherein the first switch is coupled between the internal node and the bias transistor, and the bias transistor is coupled between the first switch and the ground.
10. The system of any one of clauses 1 to 8, wherein the bias transistor is coupled between the internal node and the first switch, and the first switch is coupled between the bias transistor and the ground.
11. The system of any one of clauses 1 to 10, wherein the bias circuit comprises:
a current transistor, wherein a drain of the current transistor is coupled to a gate of the current transistor, and the gate of the current transistor is coupled to the gate of the bias transistor; and
a current source coupled between a supply rail and the drain of the current transistor.
12. The system of any one of clauses 1 to 11, wherein the third switch is coupled between a supply rail and the internal node, and the reference voltage is a supply voltage of the supply rail.
13. The system of any one of clauses 1 to 11, further comprising a reference circuit configured to generate the reference voltage, the reference circuit comprising:
a first transistor, wherein a source of the first transistor is coupled to a supply rail, a drain of the first transistor is coupled to a gate of the first transistor, and the third switch is coupled between the drain of the first transistor and the internal node; and
a second transistor, wherein a drain of the second transistor is coupled to the drain of the first transistor, and a gate of the second transistor is coupled to the output of the bias circuit.
14. The system of any one of clauses 1 to 13, wherein the output of the current cell is coupled to a current-controlled circuit.
15. The system of clause 14, wherein the current-controlled circuit comprises a current-controlled oscillator.
16. A system, comprising:
a bias circuit configured to generate a bias voltage and output the bias voltage at an output of the bias circuit; and
a current digital-to-analog converter (DAC) comprising current cells coupled in parallel, wherein each of the current cells comprises:
   a respective bias transistor, wherein a gate of the respective bias transistor is coupled to the output of the bias circuit;
      a respective first switch, wherein the respective first switch and the respective bias transistor are coupled in series between a respective internal node and a ground;
   a respective second switch coupled between the respective internal node and an output of the current DAC, wherein a control input of the respective second switch is coupled to a control input of the respective first switch; and
      a respective third switch coupled between a reference voltage and the respective internal node.
17. The system of clause 16, wherein, for each of the current cells, the current DAC further comprises a respective inverter coupled between a control input of the respective third switch and the control input of the respective first switch.
18. The system of clause 16, wherein, in each of the current cells, a control input of the respective third switch is coupled to the control input of the respective first switch.
19. The system of any one of clauses 16 to 18, wherein, in each of the current cells, the respective first switch is coupled between the respective internal node and the respective bias transistor, and the respective bias transistor is coupled between the respective first switch and the ground.
20. The system of any one of clauses 16 to 18, wherein, in each of the current cells, the respective bias transistor is coupled between the respective internal node and the respective first switch, and the respective first switch is coupled between the respective bias transistor and the ground.
21. The system of any one of clauses 16 to 20, wherein current DAC is configured to receive control signals, and each of the current cells is configured to receive a respective one of the control signals.
22. The system of clause 21, wherein, in each of the current cells, the control input of the respective first switch is configured to receive the respective one of the control signals.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value. It is also to be appreciated that the term “ground” may refer to a DC ground or an AC ground, and thus the term “ground” covers both possibilities.

It is to be appreciated that a transistor may be implemented on a chip with a stack of two or more transistors with the gates of the two or more transistors coupled together and/or two or more transistors coupled in parallel with the gates of the two or more transistors coupled together.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a bias circuit configured to generate a bias voltage and output the bias voltage at an output of the bias circuit; and
a current cell, comprising:
a bias transistor, wherein a gate of the bias transistor is coupled to the output of the bias circuit;
a first switch, wherein the first switch and the bias transistor are coupled in series between an internal node and a ground;
a second switch coupled between the internal node and an output of the current cell, wherein a control input of the second switch is coupled to a control input of the first switch; and
a third switch coupled between a reference voltage and the internal node.

2. The system of claim 1, further comprising an inverter coupled between a control input of the third switch and the control input of the first switch.

3. The system of claim 2, wherein:
the first switch comprises a first n-type field effect transistor (NFET), wherein the control input of the first switch corresponds to a gate of the first NFET;
the second switch comprises a second NFET, wherein the control input of the second switch corresponds to a gate of the second NFET; and
the third switch comprises a third NFET, wherein the control input of the third switch corresponds to a gate of the third NFET.

4. The system of claim 3, wherein the bias transistor comprises a fourth NFET.

5. The system of claim 1, wherein:
the control input of the first switch and the control input of the second switch are configured to receive a first control signal; and
a control input of the third switch is configured to receive a second control signal, wherein the first control signal and the second control signal are complementary.

6. The system of claim 1, wherein a control input of the third switch is coupled to the control input of the first switch.

7. The system of claim 6, wherein:
the first switch comprises a first n-type field effect transistor (NFET), wherein the control input of the first switch corresponds to a gate of the first NFET;
the second switch comprises a second NFET, wherein the control input of the second switch corresponds to a gate of the second NFET; and
the third switch comprises a p-type field effect transistor (PFET), wherein the control input of the third switch corresponds to a gate of the PFET.

8. The system of claim 7, wherein the bias transistor comprises a third NFET.

9. The system of claim 1, wherein the first switch is coupled between the internal node and the bias transistor, and the bias transistor is coupled between the first switch and the ground.

10. The system of claim 1, wherein the bias transistor is coupled between the internal node and the first switch, and the first switch is coupled between the bias transistor and the ground.

11. The system of claim 1, wherein the bias circuit comprises:
a current transistor, wherein a drain of the current transistor is coupled to a gate of the current transistor, and the gate of the current transistor is coupled to the gate of the bias transistor; and
a current source coupled between a supply rail and the drain of the current transistor.

12. The system of claim 1, wherein the third switch is coupled between a supply rail and the internal node, and the reference voltage is a supply voltage of the supply rail.

13. The system of claim 1, further comprising a reference circuit configured to generate the reference voltage, the reference circuit comprising:
a first transistor, wherein a source of the first transistor is coupled to a supply rail, a drain of the first transistor is coupled to a gate of the first transistor, and the third switch is coupled between the drain of the first transistor and the internal node; and
a second transistor, wherein a drain of the second transistor is coupled to the drain of the first transistor, and a gate of the second transistor is coupled to the output of the bias circuit.

14. The system of claim 1, wherein the output of the current cell is coupled to a current-controlled circuit.

15. The system of claim 14, wherein the current-controlled circuit comprises a current-controlled oscillator.

16. A system, comprising:
a bias circuit configured to generate a bias voltage and output the bias voltage at an output of the bias circuit; and
a current digital-to-analog converter (DAC) comprising current cells coupled in parallel, wherein each of the current cells comprises:
a respective bias transistor, wherein a gate of the respective bias transistor is coupled to the output of the bias circuit;
a respective first switch, wherein the respective first switch and the respective bias transistor are coupled in series between a respective internal node and a ground;
a respective second switch coupled between the respective internal node and an output of the current DAC, wherein a control input of the respective second switch is coupled to a control input of the respective first switch; and
a respective third switch coupled between a reference voltage and the respective internal node.

17. The system of claim 16, wherein, for each of the current cells, the current DAC further comprises a respective inverter coupled between a control input of the respective third switch and the control input of the respective first switch.

18. The system of claim 16, wherein, in each of the current cells, a control input of the respective third switch is coupled to the control input of the respective first switch.

19. The system of claim 16, wherein, in each of the current cells, the respective first switch is coupled between the respective internal node and the respective bias transistor, and the respective bias transistor is coupled between the respective first switch and the ground.

20. The system of claim 16, wherein, in each of the current cells, the respective bias transistor is coupled between the respective internal node and the respective first switch, and the respective first switch is coupled between the respective bias transistor and the ground.
